(19) United States
(12) Patent Application Publication
(10) Pub. No.: US 2002/0177052 A1
(43) Pub. Date: Nov. 28, 2002

(54) Means for purging an assembly cavity of an optical assembly

(76) Inventor: Michael R. Sogard, Menlo Park, CA (US)

Correspondence Address: STEVEN G. ROEDER, THE LAW OFFICE OF STEVEN G. ROEDER, 5560 Chelsea Avenue, La Jolla, CA, 92037, US

(21) Appl. No.: 09/808,755

(22) Filed: Mar. 15, 2001

(51) Int. Cl. H01L 21/26

(52) U.S. Cl. 430/9; 438/795

(57) ABSTRACT

A fluid purging assembly (10) that purges a first fluid (16) from an assembly cavity (12) of an optical assembly (14). The fluid purging assembly (10) includes a control housing (22) that defines a housing chamber (78) which is sized and shaped to enclose at least a portion of the optical assembly (14). The fluid purging assembly (10) also includes a housing pressure controller (24) for controlling a housing pressure in the housing chamber (78). As provided herein, during the fluid purging process, the fluid purging assembly (10) controls the housing pressure in the housing chamber (78) so that the housing pressure is substantially equal to a cavity pressure in the assembly cavity (12). This prevents damage to optical elements (32) within the optical assembly (14). Preferably, a cavity control system (90) is used to control the cavity pressure in the assembly cavity (12) of the optical assembly (14) so that the cavity pressure is substantially equal to an atmospheric pressure near the optical assembly (14). This also prevents damage to the optical elements (32).

### FIELD OF THE INVENTION

The present invention is directed to a fluid purging assembly and method for purging unwanted fluid from an assembly cavity of an optical assembly used in an exposure apparatus. Additionally, the present invention is directed to a cavity control system for controlling pressure and the composition of the fluid inside the assembly cavity of the optical assembly.

### BACKGROUND

Exposure apparatuses are commonly used to transfer an image from a reticle onto a semiconductor wafer. A typical exposure apparatus includes an apparatus frame, an illumination source, a reticle stage, a wafer stage, and an optical assembly which cooperate to transfer an image of an integrated circuit from the reticle onto the semiconductor wafer. The illumination source generates a beam of light energy that passes through the reticle. The optical assembly directs and/or focuses the light passing through the reticle to the wafer.

The sizes of the integrated circuits transferred onto the wafer are extremely small. Accordingly, precise directing and/or focusing of the beam of light energy by the optical assembly is critical to the manufacture of high-density semiconductor wafers.

A typical optical assembly includes a tubular shaped housing and two or more spaced apart optical elements that are secured to the optical housing. Unfortunately, depending upon the wavelength of light energy generated by the illumination source, the type of fluid between the optical elements can greatly influence the performance of the exposure apparatus. Typically, optical assemblies have air between the optical elements. As is well known, air is a gaseous mixture that is approximately twenty-one percent oxygen. Some wavelengths of light energy are absorbed by oxygen. Air also includes water vapor, carbon dioxide and other hydrocarbons, which also absorb significant amounts of the light energy within certain wavelength ranges. Even trace amounts of these unwanted fluids, i.e. ten parts per million or less, can result in significant absorption of the light energy. Absorption of the light energy can lead to losses of intensity and uniformity of the light energy. Moreover, absorption of the light energy can lead to localized heating within the optical assembly. Thus, air within the optical assembly can adversely influence the performance and accuracy of the exposure apparatus. As a consequence, the quality of the integrated circuits formed on the wafer can be adversely influenced.

One solution to the problem includes sealing the optical elements to the optical housing to form a sealed assembly cavity, and replacing the air in the assembly cavity with a weakly absorbing gas. Unfortunately, the intricate optical elements can be irreversibly distorted and/or damaged during the purging of the assembly cavity. In addition, pressure differences between the assembly cavity and atmospheric pressure can also damage the optical elements during air transport of the optical assembly or during pressure changes associated with weather fronts, for example.

In light of the above, a need exists for an exposure apparatus that is capable of generating high-resolution patterns on a semiconductor wafer. Another need exists for a fluid purging assembly for easily and efficiently purging an unwanted fluid from an optical assembly without causing damage to the optical assembly. Still another need exists for a fluid purging assembly that minimizes the amount of time and replacement fluid required to purge the optical assembly of the unwanted fluid. Additionally, the need exists for a device and method for controlling the pressure and the composition of the fluid in the optical assembly to compensate for changes in atmospheric pressure outside the optical assembly in order to prevent damage to the optical assembly.

### SUMMARY

The present invention is directed to a fluid purging assembly for purging fluid from a substantially sealed assembly cavity of an optical assembly. The fluid purging assembly includes a control housing that defines a housing chamber and a housing pressure controller. The housing chamber is sized and shaped to enclose at least a portion of the optical assembly.

Uniquely, the housing pressure controller controls a housing pressure in the housing chamber so that during fluid purging of the assembly cavity, the housing pressure in the housing chamber is substantially equal to a cavity pressure in the assembly cavity. Stated another way, the fluid purging assembly allows for fluid replacement within the assembly cavity without creating any significant differential pressure across the optical assembly or its components.

As a result thereof, the fluid purging assembly inhibits damage and/or distortion that can occur to optical elements within the optical assembly when the optical assembly is subjected to any significant pressure differential. Stated another way, the present design allows the assembly cavity to be exposed to a vacuum without damaging the optical elements. Moreover, a first fluid that absorbs light energy within the assembly cavity can be easily and efficiently replaced with a second fluid that has relatively low light energy absorption. This minimizes absorption and localized heating within the optical assembly.

Preferably, the fluid purging assembly includes a fluid exchange system in fluid communication with the assembly cavity. The fluid exchange system removes fluid from the assembly cavity and subsequently adds fluid to the assembly cavity. Preferably, the fluid exchange system removes the unwanted, first fluid from the assembly cavity, and adds the more desirable, second fluid to the assembly cavity. During this process, the housing pressure controller continuously controls the housing pressure in the housing chamber so that the housing pressure in the housing chamber is substantially equal to the cavity pressure in the assembly cavity. More specifically, the housing pressure controller removes fluid or adds fluid to the housing chamber so that the housing pressure mirrors the cavity pressure.

The present invention is also directed to a cavity control system for maintaining the cavity pressure within the assembly cavity substantially equal to an atmospheric pressure near the optical assembly. The cavity control system includes an optical pressure controller for controlling the cavity pressure in the assembly cavity. The cavity control system also includes an atmospheric monitor for monitoring the atmospheric pressure outside the optical assembly and a cavity monitor for monitoring the cavity pressure inside the assembly cavity. Importantly, the cavity control system accounts for changes in atmospheric pressure by adding fluid to, or removing fluid from, the assembly cavity. In this manner, the composition of the fluid within the assembly cavity can be controlled to prevent radiation absorption in the optical assembly. Further, the cavity control system inhibits damage to components of the optical assembly by avoiding a pressure differential between the assembly cavity and the atmosphere.

The present invention is also a method for purging a first fluid from an assembly cavity of an optical assembly. The method includes the steps of (i) providing a control housing that defines a housing chamber, the housing chamber enclosing at least a portion of the optical assembly, and (ii) controlling a housing pressure in the housing chamber so that the housing pressure in the housing chamber is substantially equal to the cavity pressure in the assembly cavity. Preferably, the first fluid is drawn from the assembly cavity, and the second fluid is added to the assembly cavity. This process is repeated until a desired percentage of the first fluid remains in the assembly cavity.

The present invention is also directed to an optical assembly, an exposure apparatus, a device and semiconductor wafer. Moreover, the present invention is also directed to a method for making an optical assembly, an exposure apparatus, a device, and a semiconductor wafer.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a perspective view of a fluid purging assembly and an optical assembly (illustrated in phantom) having features of the present invention;

FIG. 2 is a cross-sectional view taken on line 2-2 in FIG. 1;

FIG. 3A is a perspective view of one embodiment of an optical assembly having features of the present invention;

FIG. 3B is a perspective view of an alternative embodiment of an optical assembly having features of the present invention;

FIG. 4 is a cross-sectional view of the fluid purging assembly and an optical assembly illustrating commencement of a purging process;

FIG. 5 is a cross-sectional view of the fluid purging assembly and optical assembly illustrating continuation of the purging process;

FIG. 6 is a cross-sectional view of a cavity control system and an optical assembly having features of the present invention;

FIG. 7 is a side plan illustration of an exposure apparatus having features of the present invention; and

FIG. 8 is a side plan illustration of an exposure apparatus having features of the present invention, and equipped with an embodiment of the present invention.

### DESCRIPTION

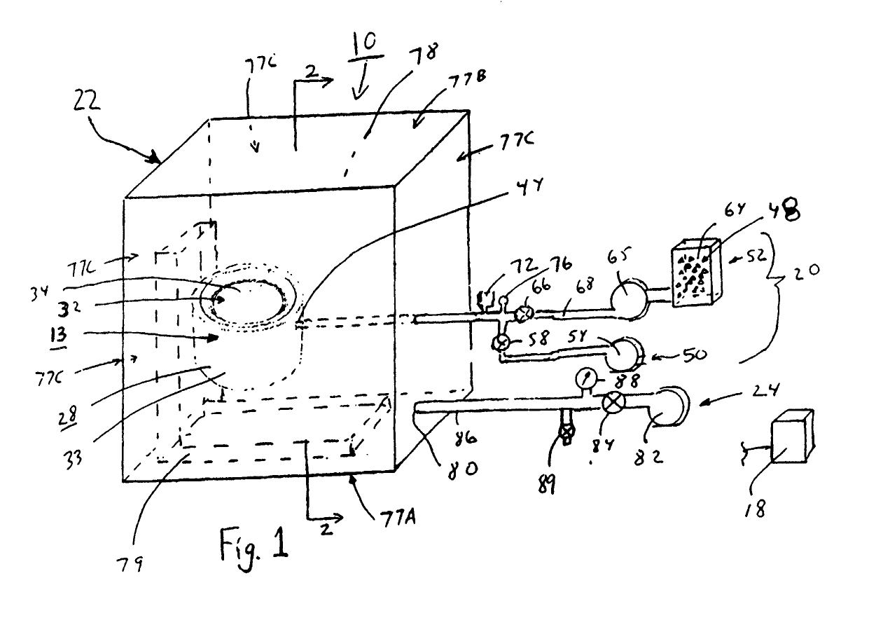

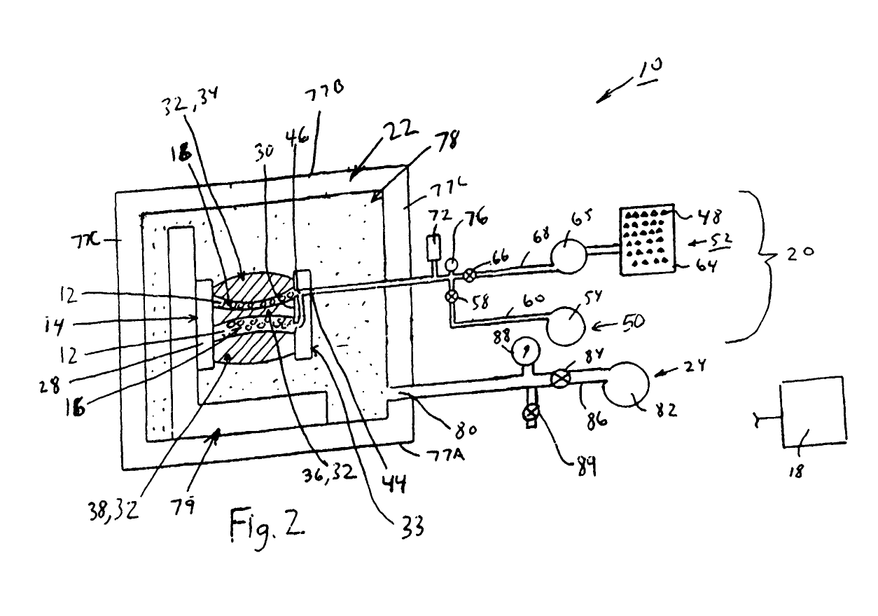

Referring initially to FIGS. 1 and 2, the present invention is directed to a fluid purging assembly 10 for purging one or more substantially sealed assembly cavities 12 of an assembly 13, and an I assembly 13 purged with the fluid purging assembly 10. Importantly, the fluid purging assembly 10 removes a first fluid 16 (represented in FIGS. 2, 4, and 5 as small circles) from each assembly cavity 12 without damaging the assembly 13 due to pressure changes within each assembly cavity 12 during the purging process. The fluid purging assembly 10 can be used for any assembly 13 where maintaining a low pressure differential is necessary to avoid damage to the assembly 13. The fluid purging assembly 10 is particularly useful for purging an optical assembly 14. As an overview, the fluid purging assembly 10 includes a purge controller 18, a fluid exchange system 20, a control housing 22, and a housing pressure controller 24.

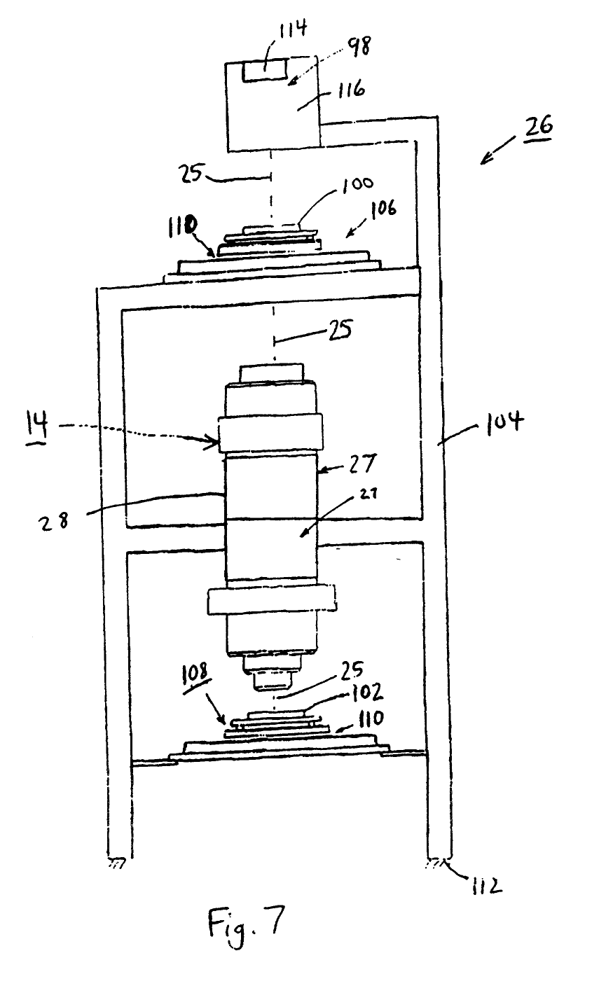

The optical assembly 14 projects, directs and/or focuses a beam of light energy 25 (shown in phantom in FIG. 7) passing through the optical assembly 14. The design of the optical assembly 14 can be varied according to its design requirements. For example, the optical assembly 14 can magnify or reduce an image to be illuminated with the exposure apparatus 26. The optical assembly 14 need not be limited to a magnification or a reduction system. The optical assembly 14 could also be a 1x system. The optical assembly 14 provided herein is particularly useful as part of an exposure apparatus 26 (illustrated in FIG. 7). Alternately, the optical assembly 14 can be used in other systems.

The optical assembly 14 includes an optical housing 28 and one or more optical elements 32 that are secured to the optical housing 28. As provided herein, the optical housing 28 and the optical elements 32 combine to define one or more sealed assembly cavities 12.

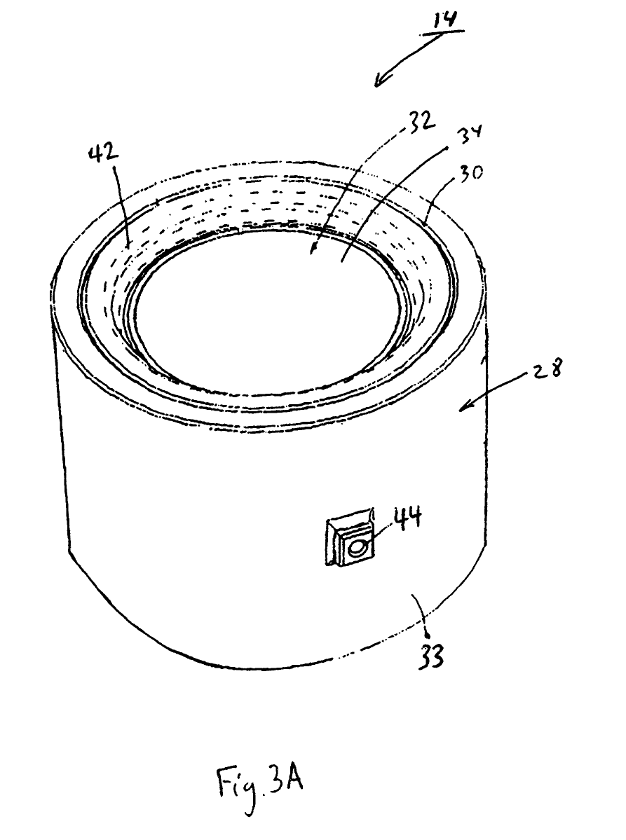

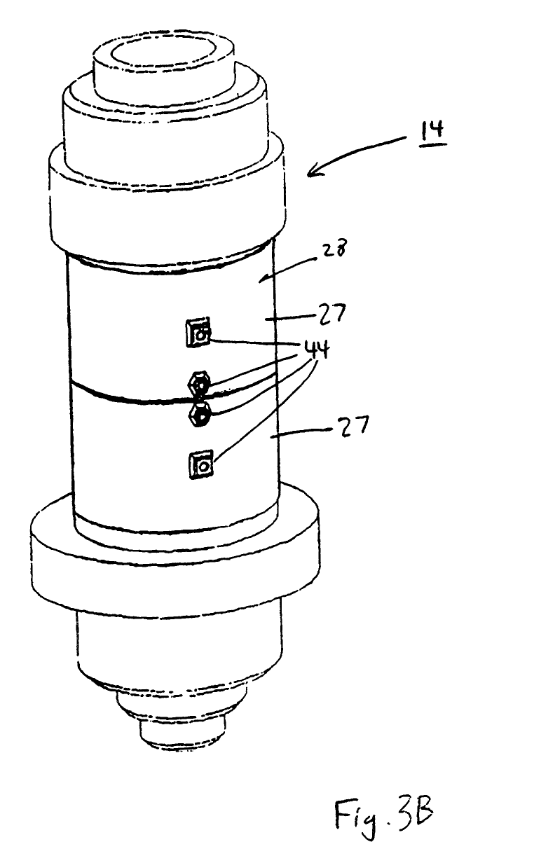

As illustrated in FIGS. 2, 3A, 4, and 5, the optical housing 28 has an inner wall 30 and an outer wall 33. Typically the optical housing 28 is substantially tubular or annular shaped and each assembly cavity 12 is substantially right, cylindrical shaped and has a circular shaped cross-section, although other shapes are also possible. In the embodiment illustrated in FIG. 3B, the optical housing 28 is divided into two housing sections 27 to facilitate assembly of the optical elements 32 to the optical housing 28.

The number of optical elements 32 utilized and the design of each optical element 32 can be varied to suit the requirements of the optical assembly 14. In the embodiment illustrated in FIGS. 2, 4, 5 and 6, the optical assembly 14 includes an upper optical element 34, a spaced-apart intermediate optical element 36, and a spaced-apart lower optical element 38 that are sealed to the optical housing 28 and which define two assembly cavities 12. Each optical element 32 is typically made of a ground or molded piece of substantially transparent material such as glass or plastic. Each optical element 32 includes opposed surfaces, either or both of which are curved so that the light rays converge or diverge. Further, each optical element 32 can be a lens, a refractive mirror, or a prism.

As can best be seen with reference to FIG. 3A, the upper optical element 34 is secured and sealed to the optical housing 28 with an upper optical element supporter 42. The upper optical element supporter 42 is annular shaped and extends between the inner wall 30 of the optical housing 28 and the upper optical element 34 to radially support the upper optical element 34. Further, upper optical element supporter 42 encircles the upper optical element 34 and seals the upper optical element 34 to the optical housing 28. The upper optical element supporter 42 can be made of a number of materials including metal, plastic or other suitable material. Although not shown in FIG. 3A, the intermediate optical element 36 and the lower optical element 38 can be secured and sealed to the optical housing 28 with similar element supporters (not shown).

The optical assembly further includes one or more fluid exchange ports 44 that extend through the optical housing 28 for purging the one or more assembly cavities 12. Preferably, the fluid exchange port 44 allows for fluid communication between the fluid exchange system 20 and the assembly cavity 12. With this design, the fluid exchange port 44 is used to replace some or all of the first fluid 16 in the assembly cavities 12 with a second fluid 48 (represented in FIGS. 2 and 4-6 as small triangles) until the level of the first fluid 16 in the assembly cavity 12 is reduced to an acceptable level. Basically, the fluid exchange ports 44 are used for either allowing fluid access into or out of the one or more assembly cavities 12.

The number and exact location of the fluid exchange ports 44 can be varied according to the design of the optical assembly 14. The optical assembly 14 illustrated in the FIGS. 2, 3A, 4, and 5 includes one fluid exchange port 44. Alternately, for example, the optical assembly 14 illustrated in FIG. 3B includes four fluid exchange ports 44. Further, the size of each fluid exchange port 44 can be varied. For the embodiments illustrated herein, each fluid exchange port 44 is an opening having a diameter of between approximately 10 and 50 millimeters.

In the embodiment illustrated in FIGS. 2, 4, and 5, one fluid exchange port 44 extends from the outer wall 33 of the optical housing 28, and divides into two fluid exchange channels 46 within the optical housing 28, between the inner wall 30 and the outer wall 33. Each fluid exchange channel 46 leads to, and allows fluid to flow to or from a separate assembly cavity 12. Alternately, two or more fluid exchange ports 44 can extend through the optical housing 28, with each fluid exchange port 44 leading to and from a separate assembly cavity 12. Still alternatively, two or more fluid exchange ports 44 can extend through the optical housing 28 into a single assembly cavity 12.

As provided above, the fluid purging assembly 10 includes the fluid exchange system 20, the control housing 22, the housing pressure controller 24, and the purge controller 18. The fluid exchange system 20 purges the first fluid 16 from the assembly cavity 12 and replaces the first fluid 16 with the second fluid 48. The design of the fluid exchange system 20 can be varied to suit the purging requirement of the optical assembly 14.

Referring to FIGS. 1 and 2, the fluid exchange system 20 includes a vacuum source 50 and a fluid source 52. The vacuum source 50 and the fluid source 52 are typically coupled via one or more of the fluid exchange ports 44 to the assembly cavity 12. The vacuum source 50 draws the fluid mixture from the assembly 12 and facilitates the efficient removal of a substantial portion of the first fluid 16 from within the assembly cavity 12. The fluid source 52 provides the second fluid 48 that replaces the fluid mixture that is removed from the optical assembly 14.

The vacuum source 50 typically includes a vacuum pump 54 that is in fluid communication with one or more of the fluid exchange ports 44. The vacuum pump 54 draws the fluid from the assembly cavities 12. The vacuum source 50 can also include a vacuum valve 58 and at least one vacuum hose 60. The vacuum valve 58 is positioned in line with the vacuum hose 60. The vacuum hose 60 connects the vacuum pump 54 to the fluid exchange port 44.

The fluid source 52 provides the second fluid 48 used during purging of the one or more assembly cavities 12. Stated another way, the fluid source 52 directs the second fluid 48 to the one or more assembly cavities 12 through the one or more fluid exchange ports 44. The design of the fluid source 52 can be varied. The fluid source 52, illustrated in the Figures, includes a fluid reservoir 64 and a fluid pump 65 that is in fluid communication with the one or more of the fluid exchange ports 44. The fluid reservoir 64 retains the second fluid 48 and the fluid pump 65 directs the second fluid 48 to the assembly cavities. The fluid source 52 can also include a fluid valve 66 and a fluid hose 68. Each fluid valve 66 is positioned in line with one of the fluid hose 68. The fluid hose 68 couples the fluid reservoir 64 and the fluid pump 65 to the fluid exchange port 44. Normally the pressure in the fluid reservoir 64 is maintained far higher than that within the assembly cavities 12, so the pump 65 may not be necessary.

The purge controller 18 controls the opening and closing of the vacuum valve 58 and the operation of the vacuum pump 54 to remove the necessary amount of the first fluid 16 or other fluids from the assembly cavities 12. Further, the purge controller 18 controls the opening and closing of the fluid valve 66 and the operation of the fluid pump 65 to create the desired flow and pressure of the second fluid 48 into the assembly cavities 12.

The second fluid 48 utilized herein can vary. Preferably, the second fluid 48 is a weakly absorbing gas to minimize absorption of light energy and localized heating within the assembly cavities 12. Suitable second fluids 48 include inert gases such as helium, argon or neon. Inert gases, as examples, absorb far less radiation than fluids sought to be purged from the assembly cavity 12 such as oxygen, water, carbon dioxide and other hydrocarbons. Nitrogen may also serve as the second fluid 48 for some radiation source wavelengths.

Preferably, the fluid exchange system 20 also includes a fluid analyzer 72 (illustrated in FIGS. 2, 4 and 5) for detecting the composition of fluid in the assembly cavity 12. The fluid analyzer 72 can discern whether unwanted fluids are present in amounts that may cause undesirable effects during use of the optical assembly 14. Preferably, the fluid analyzer 72 indicates when the percentage of oxygen, water vapor, carbon dioxide or other hydrocarbons, as examples, is acceptable or excessive. Stated another way, the fluid analyzer 72 can indicate when levels of the first fluid 16 have decreased sufficiently to allow for optimum functioning of the optical assembly 14. An acceptable level as provided herein can be approximately less than 10 parts per million (ppm), and preferably approximately less than approximately one ppm, of the first fluid 16. Examples of constituents of the first fluid 16 which can cause undesirable effects include oxygen, water and water vapor, carbon dioxide, and other hydrocarbons. Thus, an acceptable level as provided herein may be approximately single digit, parts per million (ppm) residual oxygen level, residual water level, residual carbon dioxide level, or residual hydrocarbon level, although lower levels of the first fluid 16 can be achieved with the present invention.

Additionally, the fluid exchange system 20 can include one or more cavity pressure monitors 76 for monitoring a cavity pressure within the assembly cavities 12. In embodiments of the optical assembly 14 having a plurality of assembly cavities 12, the assembly cavities 12 can be linked so that the cavity pressure is substantially equal within all of the assembly cavities 12. With this design, a single cavity pressure monitor 76 can monitor pressure within all of the assembly cavities 12 simultaneously.

The control housing 22 provides a controlled environment around the optical assembly 14 and protects the optical assembly 14 from atmospheric pressure conditions during the purging process. The control housing 22 defines a housing chamber 78 that encloses at least a portion of the optical assembly 14. The design of the control housing 22 can vary in size and shape according to the design of the optical assembly 14. Preferably, the housing chamber 78 is sized and shaped to enclose and encircle the entire optical assembly 14 including the assembly cavity 12. Referring to FIGS. 1 and 2, the control housing 22 includes a bottom wall 77A, a top wall 77B, and four side walls 77C that define the housing chamber 78. The control housing 22 also includes a bracket 79 for retaining the optical assembly 14. The control housing 22 is rigid and can be constructed from materials such as metal or plastic.

The control housing 22 also includes a control housing port 80 that extends through one of the walls 77A-77C into the housing chamber 78. The control housing port 80 is coupled to the housing pressure controller 24. The housing pressure controller 24 controls the housing pressure within the housing chamber 78.

The housing pressure controller 24 typically includes a chamber vacuum pump 82, a chamber control valve 84, a chamber hose 86 and a chamber pressure monitor 88. The chamber vacuum pump 82 is in fluid communication with the housing control port 80 and draws fluid (represented in FIGS. 2, 4, and 5 as small dots) from the housing chamber 78 through the housing control port 80. The chamber control valve 84 is positioned in line with the chamber hose 86. The chamber hose 86 couples the chamber vacuum pump 82 to the control housing port 80. The chamber pressure monitor 88 monitors the housing pressure within the housing chamber 78. In addition, an ambient gas valve 89 allows ambient gas to be added to the housing chamber 78, when the chamber pressure is below ambient atmospheric pressure.

The purge controller 18 controls opening and closing of the chamber control valve 84 and the ambient gas valve 89, and the operation of the chamber vacuum pump 82 in order to add or remove the necessary amount of air or other suitable fluid into or out of the housing chamber 78. As provided herein, the purge controller 18 is electrically connected to the cavity pressure monitor 76 and the chamber pressure monitor 88 and controls the operation of the fluid exchange system 20 and the housing pressure controller 24 so that the housing pressure inside the housing chamber 78 remains substantially equal to the cavity pressure inside the assembly cavities 12. Preferably, the purge controller 18 controls the fluid exchange system 20 and the housing pressure controller 24 so that a pressure differential between the housing pressure and the cavity pressure is less than approximately 0.1 atm and more preferably less than 0.01 atm. With this design, the housing pressure and the cavity pressure can be concurrently cycled during the purging of the assembly cavity 12.

FIGS. 2, 4 and 5 illustrate how the fluid purging assembly 10 can be used to purge the first fluid 16 from the assembly cavities 12, and replace the first fluid 16 with the second fluid 48. FIG. 2 illustrates the invention in an “at rest” state, prior to commencement of the purging process. At this stage, the first fluid 16, which is normally air, is contained within the assembly cavities 12. Typically, the “at rest” cavity pressure within the assembly cavities 12, is approximately equal to the atmospheric pressure and the housing pressure within the housing chamber 78.

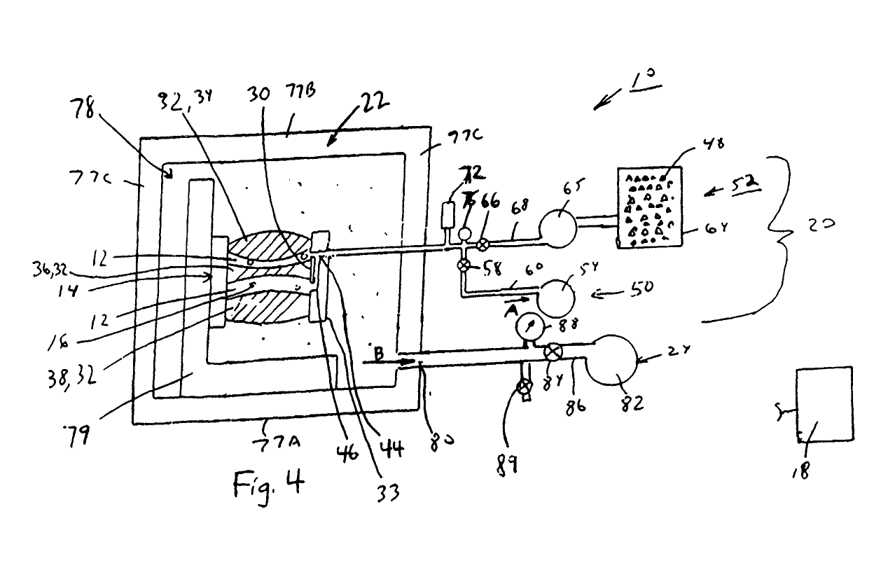

FIG. 4 illustrates commencement of the purging cycle. The vacuum valve 58 is opened and the vacuum pump 54 draws the first fluid 16 from the assembly cavities 12 as indicated by directional arrow A, thereby reducing the cavity pressure in the assembly cavities 12. Simultaneously, the chamber control valve 84 is opened and the chamber vacuum pump 82 draws the fluid from the housing chamber 78, as indicated by directional arrow B, thereby reducing the housing pressure inside the housing chamber 78. The purge controller 18 controls the fluid exchange system 20 and the housing pressure controller 24 so that the housing pressure remains nearly equal to the cavity pressure.

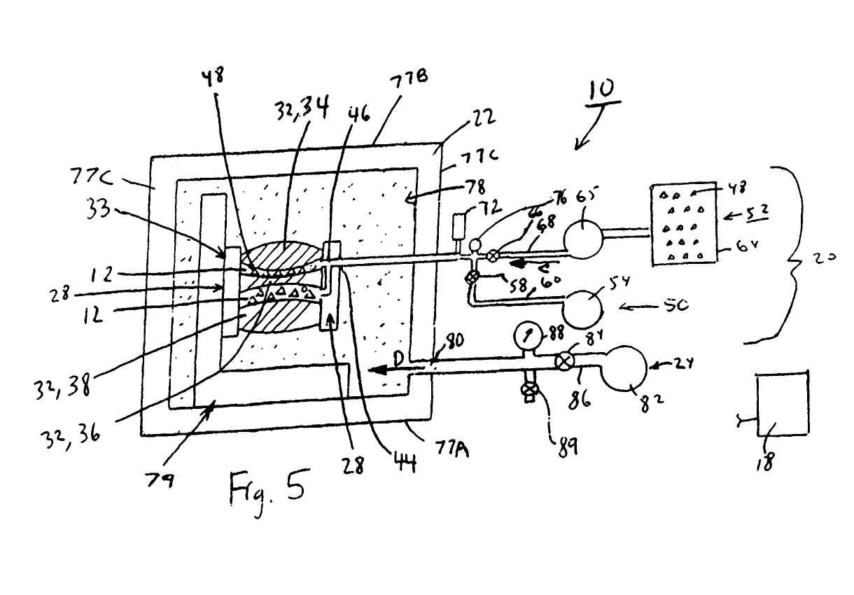

Referring to FIG. 5, once the vacuum source 50 has removed the majority of the first fluid 16, or some other desired amount, the vacuum valve 58 is closed, and the fluid source 52 begins to replace the first fluid 16 with the second fluid 48, as indicated by directional arrow C. The second fluid 48 travels from the fluid reservoir 64 through the fluid pump 65, the fluid hose 68 and the fluid valve 66. The purge controller 18 controls the cavity pressure by controlling the amount of the second fluid 48 flowing through the fluid exchange port 44 into the assembly cavities 12. Simultaneously, the chamber vacuum pump 82 directs air or another suitable fluid into the chamber hose 86, through the chamber control valve 84 and into the housing chamber 78, as indicated by directional arrow D. In this manner, the housing pressure inside the housing chamber 78 is maintained substantially equal to the cavity pressure within the assembly cavities 12. Upon filling the assembly cavities 12 with the second fluid 48 to the desired pressure, one “cycle” is said to have been completed. The desired pressure can be 1 atm, or some other pressure.

During the process outlined above and illustrated in FIGS. 2, 4 and 5, the fluid analyzer 72 measures the composition of fluid within the assembly cavities 12. At the completion of each cycle, the fluid analyzer 72 indicates the composition so that the user can determine whether another cycle is necessary. Alternatively, the fluid analyzer 72 can direct information regarding the composition of the fluid in the assembly cavities 12 to the purge controller 18 and the purge controller 18 can automatically continue with additional cycles until a predetermined maximum level of the first fluid 16 is present within the assembly cavities 12.

As an example, if the cavity pressure can be reduced by the vacuum source 50 to 1/1,000 of one atm, then the first fluid 16 level is reduced by 99.9 percent after one cycle. Further, if the first fluid 16 is assumed to be air, and if the desired maximum level of air within the assembly cavities 12 is one ppm, the number of cycles necessary to bring the level of air below the acceptable maximum would be:

| | | |
|---|---|---|
| After one cycle, | 0.1 percent × 1,000,000 | = 1,000 ppm remains. |
| After two cycles, | 0.1 percent × 1,000 | = 1 ppm remains. |

Therefore, the present invention can achieve the desired maximum percentage of the first fluid 16 in the assembly cavities 12 in just two purging cycles. In this example, at the end of two cycles, the assembly cavities 12 would be filled with 999,999 ppm of the second fluid 48, and one ppm air. This process can be used repeatedly to continue to lower the levels of the first fluid 16 below one ppm, if desired.

The above example assumes that thorough mixing occurs between the first fluid 16 and the second fluid 48 during the purging cycle. It also assumes that outgassing of the first fluid 16 from components of the optical assembly 14 is not significant. This latter condition requires that the optical assembly 14 be designed using materials, assembly techniques and construction techniques appropriate for a high vacuum system design. For example, no blind holes (not shown) where the first fluid 16 can be trapped should be allowed. All screws (not shown) and fasteners (not shown) should be vented to allow fluids to escape. Surfaces should be smooth to reduce surface area where fluids can desorb. Optical assembly components should be cleaned, stored and assembled such that contact with water vapor and organic compounds is minimized. Additional purging cycles can compensate for any potential residual outgassing. The fluid analyzer 72 can verify the condition of residual outgassing.

Importantly, during the fluid purging process, because the housing pressure substantially mirrors the cavity pressure within the assembly cavities 12, no significant differential pressure occurs. Stated another way, the housing pressure is cycled concurrently with the chamber pressure to inhibit damage to the optical elements 32 and other components of the optical assembly 14 due to pressure differentials. Further, with this design, each assembly cavity 12 can be purged of the first fluid 16 relatively easily and efficiently. Additionally, the time required to purge the optical assembly 14 is minimized and the amount of the second fluid 48 used to dilute the first fluid 16 in the assembly cavities 14 to acceptable levels is minimized.

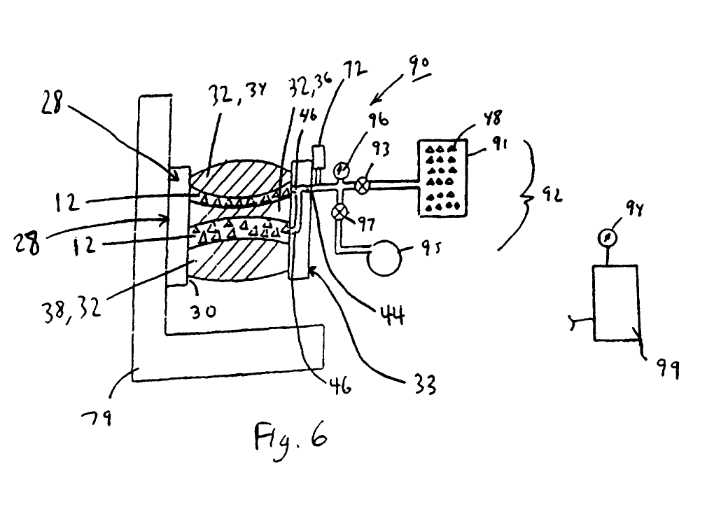

Referring to FIG. 6, the present invention is also directed to a cavity control system 90 for controlling the cavity pressure within the one or more assembly cavities 12 of the optical assembly 14. The cavity control system 90 can be used, for example, once the assembly cavities 12 have been purged using the fluid purging assembly 10 described above, or by some other means. Importantly, the cavity control system 90 adjusts the cavity pressure within the one or more assembly cavities 12 to account for changes in atmospheric pressure near the optical assembly 14 or fluid leakage from the assembly cavities 12. This inhibits damage to the optical elements 32 caused by a sufficient pressure differential across the optical elements 32.

As provided herein, the cavity control system 90 includes an optical pressure controller 92, an atmospheric monitor 94 and a cavity monitor 96. The atmospheric monitor 94 monitors atmospheric pressure immediately outside the optical assembly 14. The cavity monitor 96 monitors cavity pressure inside the assembly cavity 12. The information regarding atmospheric pressure and cavity pressure is transferred to the optical pressure controller 92.

The optical pressure controller 92 includes a fluid supply 91, a supply valve 93, a vacuum pump 95, a vacuum valve 97, and a control system 99. The fluid supply 91 is preferably filled with pressurized second fluid 48. The control system 99 compares the cavity pressure to the atmospheric pressure near the optical assembly 14. Upon detection of a pressure differential beyond any predetermined level, the control system 99 communicates with the vacuum valve 97 and/or the supply valve 93 to open or close in order to adjust the cavity pressure within the assembly cavity 12 so that the cavity pressure is substantially equal to the atmospheric pressure.

As provided herein, if the atmospheric pressure is greater than the cavity pressure by a predetermined amount, the control system 99 opens the supply valve 93 and releases the fluid 48 from the fluid supply 91 into the assembly cavity 12 until the cavity pressure is again approximately equal to the atmospheric pressure. Alternately, if the cavity pressure is greater than the atmospheric pressure, the control system 99 opens the vacuum valve 97 and operates the vacuum pump 95 until the cavity pressure is again approximately equal to the atmospheric pressure.

As an example, assume an acceptable pressure differential between the cavity pressure and the atmospheric pressure is less than approximately five percent (5%). This type of pressure differential could occur during shipping of the optical assembly 14 in an unpressurized compartment of an aircraft, for instance. If the atmospheric pressure in an unpressurized compartment drops below ninety-five percent (95%) of the cavity pressure within the assembly cavity 12 as determined by the atmospheric monitor 94 and the cavity monitor 96, the control system 99 interprets from the atmospheric monitor 94 and the cavity monitor 96 that at least a five percent (5%) pressure differential has occurred. The control system 99 then opens the vacuum valve 97 and operates the vacuum pump 95 to reduce the cavity pressure within the assembly cavity 12 until the cavity pressure is again within five percent (5%) of the atmospheric pressure, in this example.

On the other hand, if atmospheric pressure increases by six (6) percent, the control system 99 opens the fluid valve 66 and adds the second fluid 48 into the assembly cavity 12. This could occur during ground transport from a high-altitude location to a lower altitude location, for instance, or during the descent phase of an aircraft transporting the optical assembly 16 in an unpressurized compartment. Preferably, the second fluid 48 continues to flow into the assembly cavity 12 until the cavity pressure within the assembly cavity 12 is within the predetermined acceptable range relative to the atmospheric pressure.

The maximum tolerable differential pressure between the assembly cavities 12 and the immediately surrounding atmosphere is closely related to the design of the optical assembly 14. Any distortion of the optical elements 32 from the differential pressure may significantly impair performance of the optical assembly 14. However, as the internal pressure in the assembly cavities 12 is changed to compensate for the external pressure changes, the amount of fluid within the assembly cavities 12, and therefore the index of refraction of the fluid, also changes. This refractive index change could also affect performance of the optical assembly 14. Therefore, to limit changes in refractive index of the fluid, some amount of differential pressure imbalance may have to be tolerated during operation. The optical assembly 14 must be designed with sufficient mechanical rigidity so that the combined effects of refractive index change and mechanical distortion from a finite differential pressure between the assembly cavities 12 and the immediately surrounding atmosphere do not change the properties of the optical assembly 14 beyond tolerable limits over some range of atmospheric pressure change. For example, it is desirable that the optical assembly 14 be able to perform without adjustment for pressure changes comparable to those experienced during periods of normal weather. During large storms, the atmospheric pressure can change by as much as 50 millibars or more. Assuming changes of 25 millibars or less during stable weather periods, the optical assembly 14 should preferably be capable of stable performance for external pressure changes of 25 millibars or equivalently 0.025 atm. Depending on the optical assembly 14 design, the stable performance may be obtained by (i) continuously adjusting the internal pressure of the fluid to maintain zero differential pressure on the assembly cavities 12; (ii) keeping the internal pressure of the fluid constant, to maintain constant index of refraction of the fluid, and tolerating a differential pressure on the assembly cavities 12 of up to 25 millibars; or (iii) some combination of (i) and (ii).

Moreover, in some optical assemblies 14, small adjustments in an optical property, such as magnification, are sometimes accomplished by means of deliberate small changes in the pressure of the fluid filling the assembly cavities 12. In past systems the fluid has been air, but alternative fluids, such as the second fluid 48 could also be used. Therefore optical assemblies 14 which utilize this technique must be mechanically rigid enough to tolerate the resulting pressure imbalances. The accuracy of the optical pressure controller 92 must be sufficient to control the index of refraction of the fluid within the necessary optical tolerances.

Referring to FIG. 7, the optical assembly 14 provided herein is particularly useful with the exposure apparatus 26 having an illumination system 98 for the transferring of an image (not shown) from a reticle 100 to a device, e.g. a semiconductor wafer 102. The exposure apparatus 26 also includes an apparatus frame 104, a reticle stage 106, a wafer stage 108, and one or more of the motors 110 to move and position one or both of the stages 106, 108.

The exposure apparatus 26 is particularly useful as a lithographic device that transfers a pattern (not shown) of an integrated circuit from the reticle 100 onto the semiconductor wafer 102. The exposure apparatus 26 is typically mounted to a base 112.

The apparatus frame 104 is rigid and supports the components of the exposure apparatus 26. The apparatus frame 104 illustrated in FIG. 7 supports the reticle stage 106, the wafer stage 108, the optical assembly 14, and the illumination system 98 above the base 112. Alternately, for example, separate, individual structures (not shown) can be used to support the stages, the illumination system 98 and the optical assembly 14 above the base 112.

The illumination system 98 (irradiation apparatus) includes an illumination source 114 and an illumination optical assembly 116. The illumination source 114 emits the beam (irradiation) of light energy 25 that illuminates the reticle 100. The illumination optical assembly 116 guides the beam of light energy 25 from the illumination source 114 to the optical assembly 14. The beam illuminates selectively different portions of the reticle 100 and exposes the semiconductor wafer 102. In FIG. 7, the illumination system 98 is illustrated as being supported above the reticle stage 106. Typically, however, the illumination source 114 is secured to one of the sides of the apparatus frame 104 and the energy beam from the illumination source 114 is directed to above the reticle stage 106 with the illumination optical assembly 116.

In this embodiment, the optical assembly 14 projects the images of the illuminated portion of the reticle 100 onto the semiconductor wafer 102. Further, the optical assembly 14 is positioned between the reticle stage 106 and the wafer stage 108.

The reticle stage 106 holds and precisely positions the reticle 100 relative to the optical assembly 14 and the semiconductor wafer 102. Somewhat similarly, the wafer stage 108 holds and positions the semiconductor wafer 102 with respect to the projected image of the illuminated portions of the reticle 100. In the embodiment illustrated in FIG. 7, the wafer stage 108 and the reticle stage 106 are positioned by separate planar motors 110. The planar motor 110 drives the stage by an electromagnetic force generated by a magnet unit having two-dimensionally arranged magnets and an armature coil unit having two-dimensionally arranged coils in facing positions. With this type of driving system, either the magnet unit or the armature coil unit is connected to the stage and the other unit is mounted on the moving plane side of the stage. Depending upon the design, the exposure apparatus 26 can also include additional servo drive units and/or linear motors to move the stages.

There are a number of different types of exposure apparatuses 26. For example, the exposure apparatus 26 can be used a scanning type photolithography for manufacturing semiconductor wafers 102. However, the use of the exposure apparatus 26 provided herein is not limited to a photolithography system for semiconductor manufacturing. The exposure apparatus 26, for example, can be used as an LCD photolithography system that exposes a liquid crystal display device pattern onto a rectangular glass plate or a photolithography system for manufacturing a thin film magnetic head.

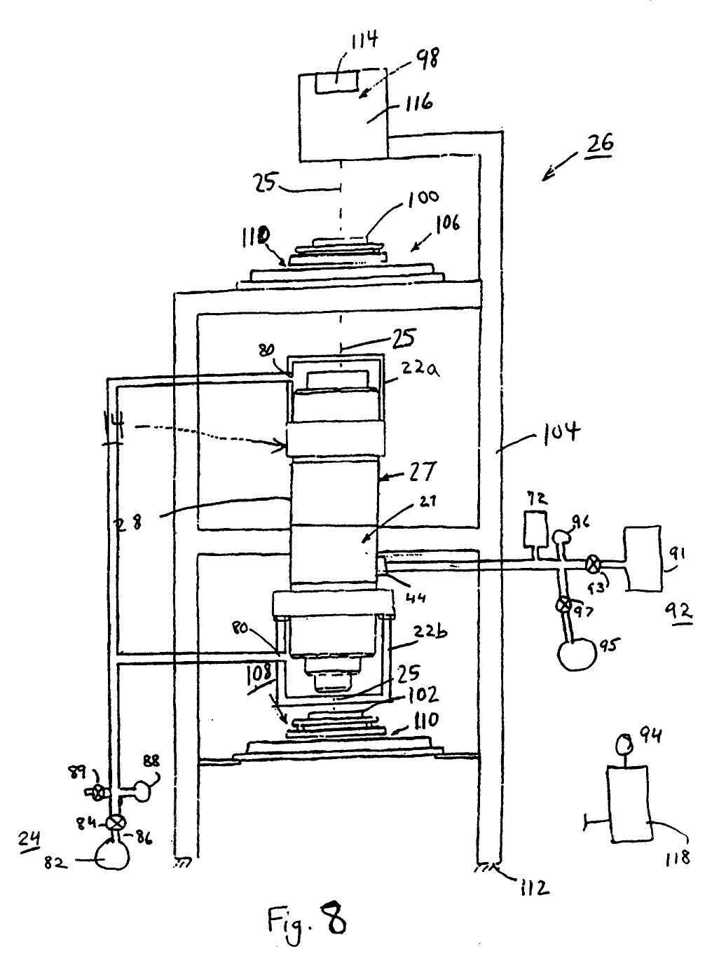

FIG. 8 shows an embodiment in which the control housing 22 contains only a portion of the optical assembly 14. In this example the housing sections 27 form a rigid cylinder, with the upper optical element 34 and lower optical element 38 exposed to atmospheric pressure. An upper control housing 22a can be mounted at the top of the optical assembly 14, to control the external pressure above the upper optical element 34, and a lower control housing 22b can be mounted at the bottom of the optical assembly 14, to control the external pressure below the lower optical element 34. Provided the housing sections 27 are sufficiently rigid to prevent deformation of internal optical components from the differential pressure occurring during purging, this embodiment has the advantage that purging can be accomplished with the optical assembly 14 mounted in the apparatus frame 104. Thus such purging could be done in the field if necessary, without requiring removal of the optical assembly 14 from the exposure apparatus 26.

It is likely the housing sections 27 are sufficiently rigid for this purpose, because the optical assembly 14 must be able to tolerate the compressive and expansive forces associated with temperature changes. The forces generated by temperature changes on the housing sections 27 will be similar to those caused by the differential pressures associated with purging.

The purging operation is controlled by a purge control system 118, which monitors the atmospheric pressure with the atmospheric monitor 94 and controls both the housing pressure controller 24 and the optical pressure controller 92.

While the particular fluid purging assembly 10, optical assembly 14 and exposure apparatus 26 as illustrated herein are fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A fluid purging assembly for purging a substantially sealed assembly cavity of an assembly, the fluid purging assembly comprising:
a control housing that defines a housing chamber, the housing chamber being sized and shaped to enclose at least a portion of the optical assembly; and
a housing pressure controller connected with the housing chamber to control a housing pressure in the housing chamber so that the housing pressure in the housing chamber is substantially equal to a cavity pressure in the assembly cavity.

2. The fluid purging assembly of claim 1 further comprising a fluid exchange system in fluid communication with the assembly cavity, the fluid exchange system controlling the cavity pressure within the assembly cavity.

3. The fluid purging assembly of claim 2 wherein the fluid exchange system removes fluid from the assembly cavity and lowers the cavity pressure in the assembly cavity.

4. The fluid purging assembly of claim 3 wherein the housing pressure controller removes fluid from the housing chamber and lowers the housing pressure in the housing chamber.

5. The fluid purging assembly of claim 4 wherein the fluid exchange system adds fluid to the assembly cavity and raises the cavity pressure in the assembly cavity.

6. The fluid purging assembly of claim 5 wherein the housing pressure controller adds fluid to the housing chamber and raises the housing pressure in the housing chamber.

7. The fluid purging assembly of claim 2 wherein the fluid exchange system controls the cavity pressure within the assembly cavity so that a pressure differential between the cavity pressure in the assembly cavity and the housing pressure within the housing chamber is less than approximately 0.1 atm.

8. The fluid purging assembly of claim 2 wherein the fluid exchange system removes a first fluid from the assembly cavity and adds a second fluid to the assembly cavity.

9. The fluid purging assembly of claim 8 wherein the second fluid is an inert gas.

10. The fluid purging assembly of claim 1 wherein the housing pressure controller controls the housing pressure within the housing chamber so that a pressure differential between the cavity pressure within the assembly cavity and the housing pressure within the housing chamber is less than approximately 0.1 atm.

11. The fluid purging assembly of claim 1 further comprising a fluid analyzer for analyzing the composition of fluid within the assembly cavity.

12. A combination including the fluid purging assembly of claim 1 and a cavity control system that controls the cavity pressure inside the assembly cavity so that the cavity pressure is substantially equal to an atmospheric pressure near the assembly.

13. The combination of claim 12 wherein the cavity control system further comprises an atmospheric monitor for monitoring the atmospheric pressure outside of the assembly; and a cavity monitor for monitoring the cavity pressure inside the assembly cavity.

14. The combination of claim 12 wherein the cavity control system further comprises a fluid exchange system in fluid communication with the assembly cavity, the fluid exchange system being adapted to remove and add a fluid to the assembly cavity.

15. The combination of claim 12 wherein the cavity control system controls pressure within the assembly cavity such that a differential pressure between the cavity pressure and the atmospheric pressure near the assembly is less than approximately 0.025 atm.

16. An optical assembly purged with the fluid purging assembly of claim 1.

17. An exposure apparatus including the optical assembly of claim 16.

18. A device on which an image has been formed by the exposure apparatus of claim 17.

19. A semiconductor wafer on which an image has been formed by the exposure apparatus of claim 17.

20. A cavity control system for controlling a cavity pressure inside a substantially sealed assembly cavity of an optical assembly, the cavity control system comprising:
an optical pressure controller connected with the optical assembly to control pressure within the assembly cavity so that a cavity pressure inside the assembly cavity is substantially equal to an atmospheric pressure near the optical assembly.

21. The cavity control system of claim 20 further comprising an atmospheric monitor for monitoring the atmospheric pressure near the optical assembly and a cavity monitor for monitoring the cavity pressure inside the assembly cavity.

22. The cavity control system of claim 20 wherein the optical pressure controller is adapted to remove and add a fluid to the assembly cavity.

23. The cavity control system of claim 20 wherein the optical pressure controller controls the cavity pressure within the assembly cavity so that a pressure differential between the cavity pressure within the assembly cavity and the adjacent atmospheric pressure is less than approximately 0.025 atm.

24. An optical assembly that includes the cavity control system of claim 20.

25. An exposure apparatus including the optical assembly of claim 24.

26. A device on which an image has been formed by the exposure apparatus of claim 25.

27. A semiconductor wafer on which an image has been formed by the exposure apparatus of claim 25.

28. A method for purging a first fluid from an assembly cavity of an optical assembly, the method comprising the steps of:
providing a control housing that defines a housing chamber, the housing chamber enclosing at least a portion of the optical assembly; and
controlling a housing pressure in the housing chamber so that the housing pressure is substantially equal to a cavity pressure in the assembly cavity.

29. The method of claim 28 further comprising the step of drawing the first fluid from the assembly cavity.

30. The method of claim 29 further comprising the step of drawing fluid from the housing chamber.

31. The method of claim 29 further comprising the step of adding a second fluid to the assembly cavity.

32. The method of claim 31 further comprising the step of adding fluid to the housing chamber.

33. The method of claim 31 wherein the steps of drawing the first fluid from the assembly cavity and adding a second fluid to the assembly cavity are repeated until a desired percentage of the first fluid remains in the assembly cavity.

34. A method for making an exposure apparatus that forms an image from a first object on a second object, the method comprising the steps of:
providing an illumination system that illuminates the first object; and
positioning an optical assembly purged by the method of claim 28 between the first object and the second object.

35. A method for making a device utilizing the exposure apparatus made by the method of claim 34.

36. A method for making a semiconductor wafer utilizing the exposure apparatus made by the method of claim 34.

37. A method for maintaining an optical assembly, the optical assembly having a substantially sealed assembly cavity, the method comprising the steps of:
controlling a cavity pressure inside the assembly cavity so that the cavity pressure inside the assembly cavity is substantially equal to an atmospheric pressure near the optical assembly.

38. The method of claim 37 wherein the step of controlling the cavity pressure further comprises the step of removing a fluid from the assembly cavity.

39. The method of claim 37 wherein the step of controlling the cavity pressure further comprises the step of adding a fluid to the assembly cavity.

40. A method for making an exposure apparatus that forms an image from a first object on a second object, the method comprising the steps of:
providing an illumination system that illuminates the first object; and
positioning an optical assembly maintained by the method of claim 37 between the first object and the second object.

41. A method for making a device utilizing the exposure apparatus made by the method of claim 40.

42. A method for making a semiconductor wafer utilizing the exposure apparatus made by the method of claim 40.

43. A method for making an optical assembly, the method comprising the steps of:
providing an optical housing;
securing at least one optical element to the optical housing to define a substantially sealed assembly cavity;
reducing a cavity pressure within the assembly cavity below the atmospheric pressure near the optical housing.

44. The method of claim 43 including the steps of (i) providing a control housing that defines a housing chamber, the housing chamber enclosing at least a portion of the optical assembly; and (ii) controlling a housing pressure in the housing chamber so that the housing pressure in the housing chamber is substantially equal to the cavity pressure in the assembly cavity.

45. The method of claim 44 further comprising the step of drawing the first fluid from the assembly cavity.

46. The method of claim 45 further comprising the step of drawing fluid from the housing chamber.

47. The method of claim 46 further comprising the step of adding a second fluid to the assembly cavity.

48. The method of claim 47 further comprising the step of adding fluid to the housing chamber.

49. The method of claim 48 wherein the steps of drawing the first fluid from the assembly cavity and adding a second fluid to the assembly cavity are repeated until a desired percentage of the first fluid remains in the assembly cavity.

50. A method for making an exposure apparatus that forms an image from a first object on a second object, the method comprising the steps of:
providing an illumination system that illuminates the first object; and
positioning an optical assembly made by the method of claim 43 between the first object and the second object.

51. A method for making a device utilizing the exposure apparatus made by the method of claim 50.

52. A method for making a semiconductor wafer utilizing the exposure apparatus made by the method of claim 50.
